(19) United States
(12) Patent Application Publication
(10) Pub. No.: US 2026/0255642 A1
(43) Pub. Date: Aug. 27, 2026

(54) FERROELECTRIC III-NITRIDE HETEROSTRUCTURES

(71) Applicant: The Regents of the University of Michigan, Ann Arbor, MI (US)

(72) Inventors: Ding Wang, Ann Arbor, MI (US); Ping Wang, Ann Arbor, MI (US); Zetian Mi, Ann Arbor, MI (US)

(21) Appl. No.: 18/992,119

(22) PCT Filed: Jul. 6, 2023
(86) PCT No.: PCT/US2023/026992

§ 371 Date: Jan. 7, 2025

Related U.S. Application Data
(60) Provisional application No. 63/359,082, filed on Jul. 7, 2022.

(51) Int. Cl. H10D 62/82; H10P 14/20

(52) U.S. Cl. CPC H10D 62/82; H10P 14/27; H10P 14/3402; H10P 14/2905

(57) ABSTRACT

A device includes a substrate and a ferroelectric layer supported by the substrate. The ferroelectric layer includes an alloy of a III-nitride material. The alloy includes a Group IIIB element. The substrate includes silicon.

### CROSS-REFERENCE TO RELATED APPLICATION

This application claims the benefit of U.S. provisional application entitled “Ferroelectric III-Nitride Heterostructures,” filed Jul. 7, 2022, and assigned Ser. No. 63/359,082, the entire disclosure of which is hereby expressly incorporated by reference.

### STATEMENT REGARDING FEDERALLY SPONSORED RESEARCH OR DEVELOPMENT

This invention was made with government support under Contract No. N00014-19-1-2225 awarded by the U.S. Office of Naval Research. The government has certain rights in the invention.

### BACKGROUND OF THE DISCLOSURE

### Field of the Disclosure

The disclosure relates generally to ferroelectric Group III-nitride materials.

### Brief Description of Related Technology

Known as the third-generation semiconductor material with wide and tunable bandgaps, high electron mobility, and high breakdown strength, III-nitride semiconductors and their heterostructures have revolutionized the semiconductor world with their excellent implementations in high frequency and high power electronics, light emitting diodes and clean energy. Recently, it has been demonstrated that robust ferroelectricity can be realized in wurtzite nitrides by alloying with Sc or B, in which the intrinsic spontaneous polarization of the nitride semiconductors can be reconfigured by an external electric field. This exciting discovery has drawn increasing interest by promising a wealth of tantalizing applications in ferroelectric memory and tunable electronic, optoelectronic, and piezo-electronic devices.

Studies of ferroelectric nitride semiconductors have been largely based on sputter deposition, which yields polycrystalline materials with the presence of extensive defects and dislocations. In this regard, significant attention has been paid to the epitaxial growth of ferroelectric nitride semiconductors, e.g., ScAlN. With the use of molecular beam epitaxy (MBE), fully epitaxial ferroelectric ScAlN and ScGaN have been demonstrated. Moreover, oxygen impurity incorporation in ScAlN, which has previously been thought to be a major limiting factor for the material quality, can be reduced by orders of magnitude by utilizing a special Ga-assisted MBE growth process. Epitaxial ScAlN has led to devices with improved properties and performance, including high electron mobility transistors (HEMTs) and memory devices that can operate at extremely high temperatures.

Despite outstanding switchable polarization and robust ferroelectricity, currently reported ScAlN films suffer severely from high leakage currents even for relatively thick ScAlN layers. Such high leakage current poses great challenges in evaluating the ferroelectric properties and further compromises their practical device applications. To reduce the leakage current, a few studies have been conducted either by changing the Sc source purity or the sputter gas ratio. Previous studies have revealed the existence of dislocation-related leakage paths in conventional III-nitride heterostructures, yet there have been no reports on the effect of crystal quality, especially dislocation density, on the electrical properties of ferroelectric ScAlN. While ferroelectricity has been measured in sputter deposited polycrystalline ScAlN, the effect of crystal quality on ferroelectric switching has remained largely unexplored. In addition, the growth kinetics, domain structures and dislocation behaviors of sputter and MBE grown materials are quite different, and there has been no systematic study regarding the effect of dislocation density on the ferroelectricity of epitaxially grown single-crystalline ScAlN films.

### SUMMARY OF THE DISCLOSURE

In accordance with one aspect of the disclosure, a device includes a substrate and a ferroelectric layer supported by the substrate. The ferroelectric layer includes an alloy of a III-nitride material. The alloy includes a Group IIIB element. The substrate includes silicon.

In accordance with another aspect of the disclosure, a device includes a substrate and a ferroelectric layer supported by the substrate. The ferroelectric layer includes an alloy of a III-nitride material. The alloy includes a Group IIIB element. The ferroelectric layer has a surface roughness less than 1 nm or less than 1% of a thickness of the ferroelectric layer.

In accordance with yet another aspect of the disclosure, a device includes a substrate and a layer supported by the substrate in a buffer-free configuration, the layer including an alloy of a III-nitride material. The alloy includes a Group IIIB element. The substrate includes silicon. The layer has a surface roughness less than 1 nm or less than 1% of a thickness of the ferroelectric layer.

In accordance with still yet another aspect of the disclosure, a method of forming a heterostructure includes providing a substrate, and implementing a non-sputtered, epitaxial growth procedure to form a ferroelectric layer supported by the substrate, the ferroelectric layer including an alloy of a III-nitride material, the non-sputtered, epitaxial growth procedure being configured to incorporate a group IIIB element into the alloy of the III-nitride material. The substrate includes silicon. The epitaxial growth procedure is implemented under a nitrogen-rich condition.

In accordance with yet another aspect of the disclosure, a method of forming a heterostructure includes providing a substrate, and implementing a non-sputtered, epitaxial growth procedure to form a ferroelectric layer supported by the substrate, the ferroelectric layer including an alloy of a III-nitride material, the non-sputtered, epitaxial growth procedure being configured to incorporate a group IIIB element into the alloy of the III-nitride material. The substrate includes silicon. Providing the substrate includes nitriding a surface of the substrate.

In connection with any one of the aforementioned aspects, the devices and/or methods described herein may alternatively or additionally include or involve any combination of one or more of the following aspects or features. The device further includes a buffer layer disposed between the substrate and the ferroelectric layer. The buffer layer includes a III-nitride semiconductor layer. The buffer layer includes the alloy of the III-nitride layer. The buffer layer is ferroelectric. The substrate and the ferroelectric layer are arranged as a heterostructure. The heterostructure lacks a buffer layer between the substrate and the ferroelectric layer. The ferroelectric layer is in contact with the substrate. The ferroelectric layer has a surface roughness less than 1 nm or less than 1% of a thickness of the ferroelectric layer. The ferroelectric layer has a dislocation density greater than 1×10¹⁰ cm⁻². The device further includes a buffer layer disposed between the substrate and the ferroelectric layer. The buffer layer includes a III-nitride semiconductor layer. The buffer layer includes the alloy of the III-nitride layer. The buffer layer includes Al, Pt, Mo and/or another metal. The substrate and the ferroelectric layer are arranged as a heterostructure. The heterostructure lacks a buffer layer between the substrate and the ferroelectric layer. The ferroelectric layer is in contact with the substrate. The substrate includes a silicon substrate with a (111) orientation. The substrate includes a metal substrate. The metal substrate includes Al, Pt and/or Mo. The device further includes a buffer layer disposed between the substrate and the layer. The buffer layer includes a III-nitride semiconductor layer. The buffer layer includes the alloy of the III-nitride layer. The buffer layer includes Al, Pt, Mo and/or another metal. The substrate and the layer are arranged as a heterostructure, and the heterostructure lacks a buffer layer between the substrate and the layer. The layer is in contact with the substrate. Providing the substrate includes nitriding a surface of the substrate. Providing the substrate further includes decomposing a native oxide on a surface of the substrate.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts a schematic view of ScAlN/GaN heterostructures grown on bulk GaN (S1), GaN/sapphire (S2), and GaN/Si (S3), along with graphical plots of the material characterization of the ScAlN/GaN heterostructures, including (b-d) 5 μm×5 μm atomic force microscopy (AFM) images of the ScAlN layers showing surface roughness measurements of (b) S1 (RMS=0.63 nm), (c) S2 (RMS=0.73 nm), and (d) S3 (RMS=0.86 nm), (e) (0002) plane x-ray diffraction (XRD) 2θ-ω scans and (f) (101̅2) plane XRD φ scans (GaN: 2θ=48.1°, χ=43.2°; ScAlN: 2θ=49.3°, χ=43.2°) of the ScAlN/GaN heterostructures (in which the φ angle for GaN of each sample is aligned for clarity, while the φ angle for ScAlN is shifted accordingly), and (g, h) full width at half maximum (FWHM) plots of (g) (0002) plane and (h) (101̅2) plane XRC for GaN (squares) and ScAlN (circles).

FIG. 2 depicts graphical plots of the ferroelectric properties of the ScAlN/GaN heterostructures of FIG. 1, including (a) P-E loops measured directly using a triangular waveform at 40 kHz (the unclosed box-shape loops for heterostructures S2 and S3 indicate high leakage current under positive bias), (b) I-E loops measured using a triangular waveform at 10 kHz (in which an increase of positive leakage current from heterostructures S1 to S3 can be seen), and (c) a positive-up, negative-down (PUND) measurement of polarization results showing the saturation of polarization in all three heterostructures, and in which the pulse width (PW) is 0.012 ms.

FIG. 3 depicts graphical plots of the electrical properties of the ScAlN/GaN heterostructures of FIG. 1, including (a) representative I-V curves recorded after positive poling for heterostructures S1-S3 (with the vertical gray line indicating a leakage current at 50 V), (b) a fitting of the leakage current shown in part (a) using a Poole-Frenkel model (in which all three curves use a universal dielectric constant of 11.6), (c) a distribution of breakdown field versus leakage current recorded on 10 devices on each heterostructure (with leakage currents measured at 50 V, which is beyond the polarization switching voltage (about 40 V) under quasi-static electrical measurements, and (d) average leakage current (at 50 V) and average breakdown field as a function of the total dislocation density of the ScAlN layer (with error bars indicative of standard deviation).

FIG. 4 depicts (a) a schematic view of a device having a ScAlN layer supported by, and in contact with, a Si substrate, in accordance with one example, (b) reflection high-energy electron diffraction (RHEED) patterns for the Si surface with 7×7 reconstruction (lower panel) and ScAlN layer (upper panel), and (c) a graphical plot of XRD 2θ-ω scans for the ScAlN/Si heterostructure, showing the characteristic diffraction peak for wurtzite ScAlN at 36°.

FIG. 5 depicts a cross-sectional, schematic view of a device having a heterostructure with an epitaxially grown ferroelectric wurtzite layer in accordance with one example.

FIG. 6 is a flow diagram of a method of fabricating a heterostructure having an epitaxially grown ferroelectric wurtzite layer in accordance with one example.

FIG. 7 depicts a schematic view of a ferroelectric transistor device with a heterostructure having a buffer-free ferroelectric layer of an alloy of a III-nitride material (e.g., ScₓAl₁₋ₓN) in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Devices having a III-nitride alloy layer are described. In some cases, the III-nitride alloy layer is ferroelectric, such as a ferroelectric ScAlN layer. In some cases, the III-nitride alloy layer is supported by a substrate composed of, or otherwise including, silicon. The III-nitride alloy layer may be in contact with the substrate or otherwise be buffer-free. In some cases, the III-nitride alloy layer has a surface roughness less than 1% of the thickness of the layer. The substrate and the III-nitride alloy layer supported thereby may be used in a variety of heterostructure arrangements and corresponding devices. Methods for fabricating such heterostructures and devices are also described.

The disclosed heterostructures and devices may integrate ferroelectric ScAlN and other III-nitride alloys with silicon (Si), e.g., Si wafers. Such integration provides a platform for a wide range of next-generation devices and systems, including, for instance, system on chip (SoC), intelligent edge, edge computing memories, and energy efficient transistors. Numerous efforts have been made to address the challenges associated with the lattice mismatch and thermal expansion coefficient mismatch for the epitaxial growth of III-nitride materials on Si. To date, however, high densities of defects and dislocations (10⁹ to 10¹⁰ cm⁻²) have been largely unavoidable for III-nitride heterostructures integrated on Si.

The electrical properties of ScAlN in the presence of extensive defects and dislocations are addressed herein to shed light on their impact on the ferroelectric properties of the III-nitride alloys and heterostructures.

Although described in connection with examples of epitaxially grown ScₓAl₁₋ₓN layers, the disclosed methods and devices may be applied to a wide variety of III-nitride alloys. The disclosed methods and devices may thus include or involve the incorporation of scandium into other III-nitride wurtzite structures. For instance, the disclosed methods and devices may include or involve one or more epitaxially grown ScₓAl_{y}Ga_{1-x-y}N layers, ScₓGa₁₋ₓN layers, or ScₓIn₁₋ₓN layers. The configuration, construction, fabrication, and other characteristics of the heterostructures may also vary from the examples described. For instance, the heterostructures may include any number of epitaxially grown layers of ferroelectric and non-ferroelectric nature.

The disclosed methods and devices are also not limited to III-nitride alloys including scandium. For instance, the III-nitride alloys may include additional or alternative group IIIB elements, such as yttrium (Y) and lanthanum (La).

Although some aspects of the disclosed methods are described in connection with MBE growth procedures, additional or alternative non-sputtered epitaxial growth procedures may be used. For instance, metal-organic chemical vapor deposition (MOCVD) and hydride vapor phase epitaxy (HVPE) growth procedures may be used. Still other procedures may be used, including, for instance, pulsed laser deposition and atomic layer deposition procedures.

The disclosed devices and methods may be useful in connection with a variety of nitride-based devices and circuits, including, for instance, nitride-based complementary logic integrated circuits. The devices and circuits may or may not be supported by, or otherwise integrated with silicon (e.g., silicon substrates).

At the outset, three sample heterostructures are described to address the impact of dislocation density on the ferroelectric properties of ScAlN layers grown by epitaxy. The sample heterostructures are used to investigate the impact of dislocation density on the ferroelectric and electrical characteristics of the ScAlN layer. The three sample heterostructures are grown on bulk GaN (sample S1), GaN on a sapphire substrate (sample S2), and GaN on a Si substrate (sample S3) using molecular beam epitaxy (MBE). Each of the sample ScAlN heterostructures accordingly includes a GaN buffer or other GaN layer underlying the ScAlN layer.

As described below, each of the sample ScAlN heterostructures is found to have an atomically smooth surface. The terms “atomically smooth” may be used herein in connection with layers of a heterostructure to indicate a layer having a surface roughness (e.g., a root mean square, or RMS, roughness) less than 1 nm. In some cases, the RMS roughness of such atomically smooth layers is less than 1% of the thickness of the layer. A single-crystalline wurtzite structure is also confirmed for each of the sample ScAlN heterostructures.

Each of the sample ScAlN heterostructures exhibits clear ferroelectric polarization switching. The ScAlN layer in each heterostructure is ferroelectric despite nearly three orders of magnitude of variation in the dislocation densities of the underlying GaN buffer layers. It is observed, however, that the enhanced leakage current for samples with high dislocation densities results in unclosed P-E loops and overestimated remnant polarization values. Furthermore, the dislocation density dependent leakage current and breakdown strength are investigated using quasi-static electrical measurements. With a reduction of dislocation density, both leakage current and breakdown strength can be improved. The investigation reveals that trapping/detrapping assisted transport and tunneling under high fields are the main leakage mechanisms in the ferroelectric ScAlN films. This insight into the impact of crystal quality on the ferroelectric characteristics of ScAlN layers supports the integration of ScAlN and other III-nitride alloys with different materials systems, such as silicon, as described herein.

The ScAlN/GaN heterostructures described herein were grown by a Veeco GENxplor MBE system with a base chamber pressure of 10⁻¹¹ Torr on three types of metal-polar GaN substrates: 600-μm-thick bulk GaN grown by hydride vapor phase epitaxy (HVPE) (sample S1), a 5-μm-thick GaN/sapphire template grown by metal organic chemical vapor deposition (MOCVD) (sample S2), and a 700-nm-thick GaN/Si template grown by MBE (sample S3). Dislocation densities of the GaN buffer layers for samples S1, S2 and S3 were found to vary in a n approximate range of 10⁷ to 10¹⁰ cm⁻². Active nitrogen (N*, 7N purity) species were provided by a Vecco RF UNI-Bulb plasma source, while gallium (Ga, 7N purity), aluminum (Al, 6N5 purity), scandium (Sc, 5N purity), and silicon (Si, 6N purity) sources were supplied using Knudsen effusion cells.

Before transfer into the growth chamber, the GaN-based substrates were outgassed in the load-lock and preparation chamber at 200 and 600° C. for 2 h, respectively. The growth temperature was monitored by a thermocouple located at the backside of each substrate, and the growth temperature for different substrates was calibrated by observing the desorption behavior of Ga adatoms on the initial surface.

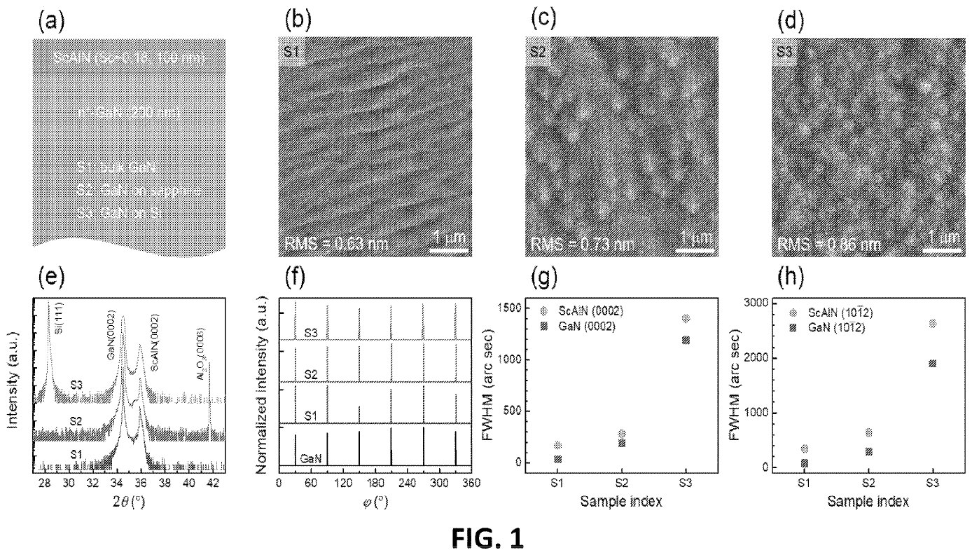

Part a of FIG. 1 displays the schematic of the ScAlN/GaN heterostructures. 200-nm-thick Si-doped n⁺-GaN was firstly grown on the GaN substrates, followed by a 100-nm-thick ScAlN layer with a nominal Sc content of 18%. The GaN layer was grown at 700° C. with a growth rate of about 200 nm/h. For the ScAlN layer, the Sc content was controlled by adjusting the Al and Sc flux. Before performing ScAlN growth, residual Ga adatoms on the surface were consumed by nitridation. This growth interruption prevents the unintentional incorporation of Ga into the ScAlN layer. All growth procedures were implemented in one batch, and the growth conditions for all three samples were kept the same to have a meaningful comparison of the effect of dislocation density on the ferroelectric properties. Further details regarding the growth conditions, including, for instance, the flux and temperature values, may be found in Wang, P., et al., “Molecular beam epitaxy and characterization of wurtzite ScₓAl₁₋ₓN,” Appl. Phys. Lett. 116 (15), 151903 (2020), and Wang, P., “Quaternary alloy ScAlGaN: A promising strategy to improve the quality of ScAlN,” Appl. Phys. Lett. 120 (1), 012104 (2022), the entire disclosures of which are hereby incorporated by reference.

The entire growth was in situ monitored by a reflection high energy electron diffraction (RHEED) system. The surface morphology was characterized using a Bruker ICON AFM, while the film thickness and Sc content were confirmed utilizing a Hitachi SU8000 scanning electron microscope (SEM) equipped with an energy dispersive X-ray spectroscopy (EDS). Post-growth XRD 2theta-omega (2θ-ω), phi (φ), and omega (ω) scans, i.e., rocking curve (XRC), were carried out using a Rigaku SmartLab diffractometer with a Cu K_{α1} radiation X-ray source (1.5406 Å). Ferroelectric and quasi-static electrical measurements were performed by a Radiant Precision Multiferroic II Ferroelectric Test System and a B1500 semiconductor analyzer in atmosphere ambient at room temperature. The n-type GaN layer was used as bottom contact (return), while circular Ti/Au top electrodes with a diameter of 20 μm were patterned lithographically on the ScAlN surface (drive).

To explore the effect of crystal quality on the ferroelectric and electrical properties of ScAlN/GaN heterostructures grown by MBE, GaN substrates with different dislocation densities were used to modulate the crystal quality of the subsequent ScAlN. Part (a) of FIG. 1 shows the schematic of the ScAlN/GaN heterostructures. Parts (b)-(d) of FIG. 1 present the AFM images for the ScAlN/GaN heterostructures, showing root mean square (RMS) roughness of 0.63, 0.73, and 0.86 nm for a scanning area of 5 μm×5 μm for samples S1, S2, and S3, respectively. All of the ScAlN surfaces show the presence of nano-grains. Notably, before starting GaN regrowth on the bulk GaN substrate, a five cycle Ga deposition-desorption surface pretreatment was executed to obtain a clean surface, which is also beneficial for getting a step-flow GaN surface. The ScAlN layer grown on bulk GaN shows a wavy step-flow surface morphology (see part (b) of FIG. 1), which follows the step-flow surface of the bulk GaN. However, hillocks are observed on the surface of the ScAlN layer grown on both GaN/sapphire and GaN/Si substrates (see parts (c) and (d) of FIG. 1). This feature is also an inheritance of the underlying GaN surface, in which hillocks with spiral atomic steps will form around the screw threading dislocations during MBE growth. The threading dislocation associated hillocks have a relatively high density on the ScAlN/GaN/Si surface, indicating a low crystal quality.

Part (e) of FIG. 1 presents the (0002) plane XRD 2θ-ω scans for the ScAlN/GaN heterostructures. A characteristic diffraction peak at 36° is observed for all three samples, and no other diffraction peaks from other asymmetric planes are observed in the long-range scan (20-100°), indicating a wurtzite crystal structure for the ScAlN films. The small bump between the GaN and ScAlN diffraction peaks for sample S2 is from the buffer layer used for the high-quality commercial GaN growth on sapphire substrates. To further clarify the uniformity of in-plane orientation, XRD φ scans were carried out on the asymmetric (101̅2) plane for both GaN and ScAlN using the same chi (χ=43.2°) angle, while the 2θ angles were set to the corresponding diffraction peak positions, as shown in part (f) of FIG. 1. Six sharp peaks separated by 60°, aligned with the underlying GaN, are observed for all ScAlN samples, confirming the six-fold symmetry for a wurtzite structure, the epitaxial registry between GaN and ScAlN, as well as the single-crystalline nature of the epitaxially grown films.

The dislocation density was evaluated by performing XRC measurements on the symmetric (0002) plane and the asymmetric (101̅2) plane for both the GaN and ScAlN layers. Parts (g) and (h) of FIG. 1 show the (0002) and (101̅2) planes full-width-at-half-maximum (FWHM), respectively. Overall, the crystal quality of ScAlN highly depends on the quality of underlying GaN layer and exhibits a somewhat lower quality than GaN. The total dislocation densities estimated from the XRC FWHM for GaN are 6.8×10⁷, 8.8×10⁸, and 3.5×10¹⁰ cm⁻² for samples S1, S2, and S3, respectively. To estimate the dislocation density of the ScAlN layers, the lattice parameters deduced from (0002) and (101̅2) plane XRD 2θ-ω scans were used, which are a=3.175 Å and c=4.985 Å, respectively. The deduced total dislocation densities for the ScAlN layers are 1.3×10⁹, 4.6×10⁹, and 7.4×10¹⁰ cm⁻² for samples S1, S2, and S3, respectively. Even though grown on bulk GaN, the ScAlN layer of sample S1 still presents a relatively high dislocation density, which is primarily contributed by the edge dislocations (1.3×10⁹ cm⁻² for sample S1). The predominant contribution of edge dislocations indicates the existence of a vertical domain wall/boundary.

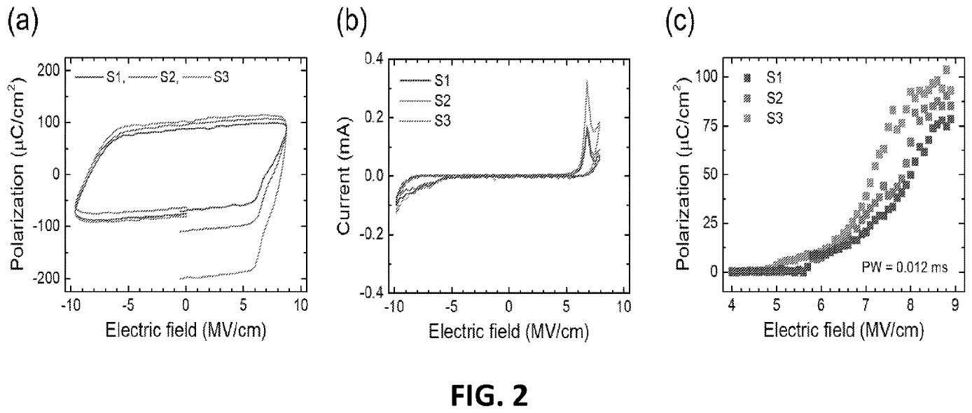

To compare the ferroelectricity in the different samples, P-E and I-E loops as well as PUND measurements were performed under identical measurement conditions. As shown in part (a) of FIG. 2, all three samples showed box-shape P-E loops, with a remnant polarization of about 90 μC/cm². For samples S2 and S3, the unclosed box indicates enhanced leakage current under positive bias. Part (b) of FIG. 2 shows the I-E loops of the samples, in which an increase in current is observed in samples S2 and S3 with higher dislocation densities, consistent with part (a) of FIG. 2. The somewhat slow and weak switching in the negative branch could be ascribed to the multiple strain states in the ScAlN films and a space charge region in the n-GaN side. It is also noticed that after switching, the currents under positive bias are higher than those under negative bias, which can be understood by the difference in electrode configurations, band profiles, and trap states. For symmetric electrode configurations, the leakage current in both positive and negative branches may increase symmetrically, leading to closed P-E loops but overestimated polarization values.

Part (c) of FIG. 2 shows the PUND measurement results obtained using trapezoidal pulses with a pulse width of 0.012 ms and delay time of 1000 ms. The values shown are the averaged remnant polarization from both branches. Despite that all three samples show good saturation behavior, the extracted remnant polarization shows a noticeable increase with reduced film quality. While the PUND measurements have been shown to compensate the non-switching current from resistive leakage and dielectric responses to verify the presence of saturated remnant polarization in ferroelectrics, the observed slight increase in remnant polarization suggests that it is yet difficult to completely compensate the leakage current in the ScAlN films.

Quasi-static electrical measurements were performed to further investigate the electrical properties of the ScAlN/GaN heterostructures. Before each measurement, the polarity was pre-poled downward to make sure no switching current contributes to the total measured current. Besides, the positive branch with polarization pointing downward is chosen so that the GaN electrode is under accumulation and voltage drops mostly in the ScAlN layer.

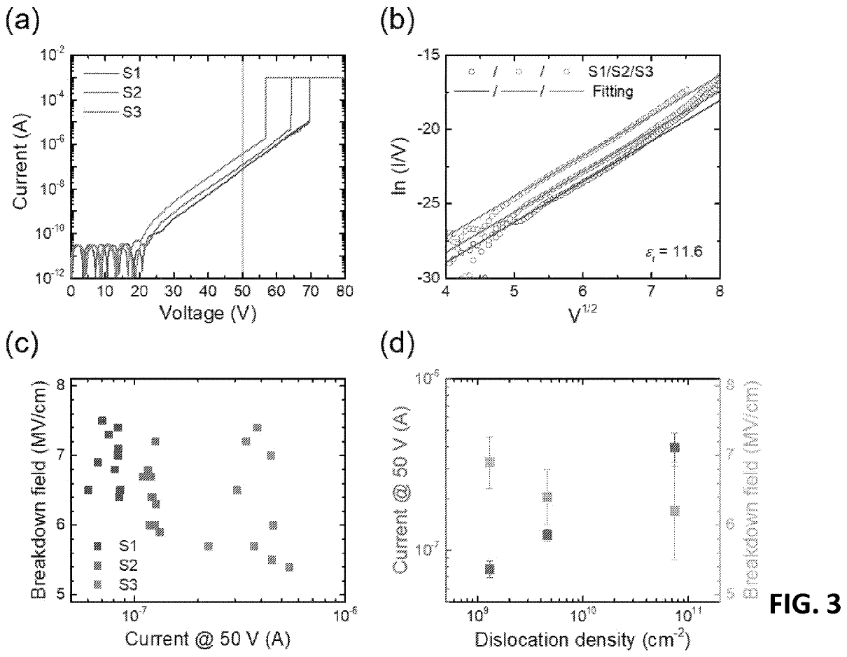

Part (a) of FIG. 3 shows the current-voltage (I-V) curve measured for biases ranging from 0 to 80 V for all three samples. The ScAlN grown on bulk GaN exhibited the lowest leakage current, whereas the ScAlN grown on GaN/Si possesses a relatively higher leakage, which is consistent with the above ferroelectric measurements. For thick dielectrics, the leakage current is usually attributed to trap-assisted processes. As shown in part (b) of FIG. 3, it is found that in the low bias voltage region, the three curves can be well-fitted by the Poole-Frenkel emission model using a universal dielectric constant of 11.6, suggesting that at low bias voltages, the electron transport is dominated by trap-assisted processes. The fitted dielectric constant is consistent with previous reports. According to the Poole-Frenkel model, as the intercept gets smaller, the activation energy increases. In this regard, the emission activation energy for sample S1 is found to be about 0.018 eV, which is about 0.04 eV higher than those of samples S2 and S3. The upward shift of the curves with increasing dislocation density, i.e., from sample S1 to sample S3, indicates that dislocations in ferroelectric the ScAlN films are not acting as direct resistive leakage pathways, but rather behaving like traps with reduced activation energies. Another possible explanation is that dislocations may introduce resistive continuum states below the conduction band and lower the energy needed for Poole-Frenkel emission. With higher bias voltages, a triangular barrier is expected to form at the ScAlN/GaN interface, and electrons can tunnel through the barrier and contribute to the overall current, causing a faster increase of current compared with pure Poole-Frenkel model. Because both processes are strongly electric-field-dependent, reducing the coercive field of the ferroelectric ScAlN layer may mitigate the adverse effect of leakage current. Due to incomplete charge compensation at the ScAlN/GaN interface, a depolarization field forms in the ScAlN layer with a direction opposite to that of the applied electric field. This depolarization field may also shift the I-V curves as shown in parts (a) and (b) of FIG. 3. The fact that a reasonable dielectric constant can be obtained without considering the depolarization field at the interface, together with the almost identical coercive field for different samples as shown in part (b) of FIG. 2, indicates that the depolarization field in connection with these samples is not significant, which may be ascribed to the complicated domain structure or high trap density near the interface.

To clarify the variation from device to device, the leakage current (at 50 V) and breakdown field for 10 random distributed devices of each sample are presented in part (c) of FIG. 3. Part (d) of FIG. 3 further depicts the corresponding average leakage current and breakdown field for those 10 devices versus the total dislocation density of the ScAlN layer. For the ScAlN layers grown on the bulk GaN and GaN/sapphire substrates, the leakage current shows minor fluctuation with a standard deviation (σ) of 8.3×10⁻⁹ and 1.0×10⁻⁸ A, respectively. For all devices of samples S1 and S2, even though the breakdown field has a variation in the range of 5.8-7.6 MV/cm (σ=0.38 MV/cm), the overall leakage current trend and values barely changed. However, for the devices with a ScAlN layer grown on the GaN/Si substrates, both leakage current and breakdown field exhibited a scattered distribution with a standard deviation of 8.7×10⁻⁸ A and 0.7 MV/cm, respectively.

As shown in part (d) of FIG. 3, both leakage current and breakdown field highly depend on the crystal quality of the ScAlN layer, i.e., a higher dislocation density results in a higher leakage current with a lower breakdown strength, which was also supported by contact-area dependent measurements. The increased non-uniformity in the ScAlN layer grown on the GaN/Si substrate compared with those grown on bulk GaN and GaN/sapphire templates is attributed to the high dislocation density of the film, which introduces more scattering and noise that may trigger breakdown.

Based on the analysis above, it is therefore reasonable to conclude that the existence of a high density of threading dislocations does not, in and of itself, block the presence of ferroelectricity, but rather introduces instabilities in the breakdown behaviors and increased leakage current via traps. Trapping/detrapping assisted transport and tunneling under high fields are believed to be the main leakage mechanisms in the ferroelectric ScAlN films over the entire dislocation density range investigated. Such traps may stem from low-purity Sc sources, the high oxygen-affinity of Sc and Al, nitrogen vacancies, and dislocation or domain boundaries. The coupling of traps and micro-domain structure dominates the electrical properties, especially the breakdown strength of ferroelectric ScAlN films.

The sample heterostructures addressed in FIGS. 1-3 investigated the effect of dislocation density on the ferroelectric properties of ScAlN films grown by MBE. As described above, ScAlN layers were grown on GaN substrates with various levels of dislocation densities. With the above-described samples, it was established that the presence of massive dislocations does not block or prevent the observation of ferroelectricity in the as-grown ScAlN films, but rather results in enhanced unclosed P-E loops in asymmetric electrode configurations and overestimated polarization values. The investigation further revealed that the reduction in dislocation density can lower the leakage through traps and enhance the breakdown strength of the epitaxially grown films. With this information in hand, the material quality considerations for integrating ferroelectric ScAlN layers with different semiconductor platforms (e.g., silicon platforms) have been provided, thereby building the basis for next generation devices, including, for instance, electronic, optoelectronic, and piezoelectronic devices.

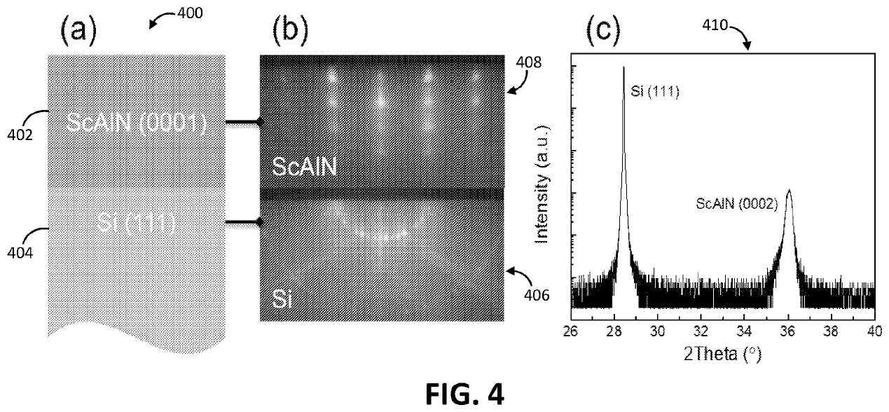

FIG. 4 depicts a device 400 having a buffer-free III-nitride alloy layer 402 supported by a substrate 404 in accordance with one example. In this case, the substrate 404 is composed of, or otherwise includes, silicon. For instance, the silicon substrate 404 may or may not be doped. In some cases, the silicon substrate 404 has a (111) orientation.

The supported III-nitride alloy layer 402 is composed of, or otherwise includes, an alloy of a III-nitride material. The alloy includes a Group IIIB element. In this example, the III-nitride alloy is ScAlN. Alternative or additional III-nitride materials may be used, including, for instance, alloys of III-nitrides that include another group III element, such as Ga. Alternative or additional Group IIIB elements may be used, including, for instance, yttrium (Y) and lanthanum (La).

In some cases, the III-nitride alloy layer 402 is ferroelectric. The substrate 404 and the ferroelectric layer 402 are arranged as a heterostructure. In the example of FIG. 4, the heterostructure lacks a buffer layer between the substrate 404 and the ferroelectric layer 402. In this case, the ferroelectric layer 402 is in contact with the substrate 404. The device 400 thus provides an example of buffer-free direct epitaxial heterointergration between single-crystalline wurtzite phase ScAlN and Si. In other buffer-free arrangements, another, non-buffer layer or other structure is disposed between the ferroelectric layer and the substrate, such as a metal layer (e.g., Mo, Al, etc.).

As in the sample heterostructures described above, in some cases, the ferroelectric layer 402 has an atomically smooth surface. For instance, the ferroelectric layer 402 may have a surface roughness (e.g., an RMS roughness) less than 1% of the thickness of the ferroelectric layer. In an example with a layer thickness of 100 nm, the RMS roughness is less than 1 nm. The surface roughness may be achieved via the growth conditions, parameters, and other aspects of the fabrication processes described and/or referenced herein and/or other processes.

In one example, the epitaxial growth of wurtzite ScAlN on silicon shown in FIG. 4 was achieved as follows. A number of single side polished 2-inch n-type (N/As) Si(111) (<111>±0.5°) wafers with a resistivity of 0.001-0.005 ⋅·cm were provided as a substrate. The thickness of the Si(111) substrates was in the range of 254-304 μm. The Si(111) wafers were etched in buffered HF at room-temperature for 2 min to remove the surface oxidation layer, and further cleaned by deionized water prior to loading into the MBE system. The Si(111) substrates were then baked and degassed at 200 and 600° C. for 2 h in the MBE load-lock chamber and preparation chamber, respectively. In the growth chamber, the Si(111) substrates was heated up to 900° C. to completely decompose the native oxide. The substrate temperature was lowered to 800° C. for ScAlN growth without using any buffer layer.

To avoid the impact or formation of a metal-Si eutectic (Al/Sc—Si) on the initial nucleation, a 60 second surface nitridation (e.g., activate the nitrogen plasma, then apply the nitrogen plasma with the Sc and Al shutters closed) was implemented before starting ScAlN growth. During the ScAlN growth, a nitrogen rich growth condition was used to avoid the formation of intermetallic, perovskite, and eutectic layers.

Part (b) of FIG. 4 shows the reflective high energy electron diffraction (RHEED) patterns 406, 408 recorded at the end of ScAlN growth for the Si surface with 7×7 reconstruction (lower panel) and ScAlN layer (upper panel), respectively. Single set spotty RHEED patterns for a wurtzite crystal structure are present. The single-crystalline wurtzite crystal structure is further confirmed using x-ray diffraction, shown in a graphical plot 610 of part (c) of FIG. 4, in which the characteristic diffraction peak for wurtzite ScAlN located at about 36° is present.

The afore-mentioned growth conditions and process parameters may vary in other cases. For instance, a ferroelectric ScAlN layer may also be grown on a Si substrate by using other growth conditions for ScAlN layers, such as those described elsewhere herein and in the publications referenced herein.

The heterostructure may include any number of layers, structures, and/or components in accordance with the functionality of the device.

In other examples, a substrate other than a silicon substrate is used. For instance, the substrate may be composed of, or otherwise include, SiC or sapphire.

In other examples, the layer supported by the substrate is not ferroelectric.

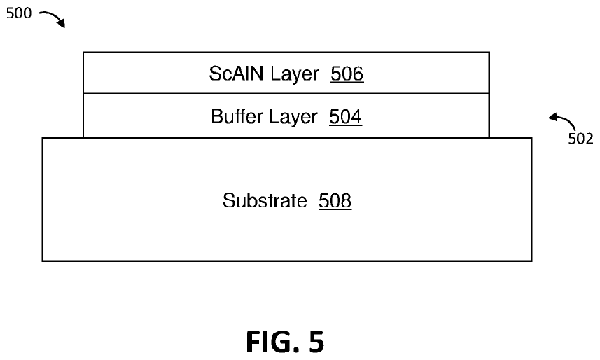

FIG. 5 depicts a device 500 having a heterostructure 502 with a buffer layer 504 disposed between a III-nitride alloy layer 506 and a substrate 508 in accordance with one example. The III-nitride alloy layer 506 and the substrate 608 may have a composition, configuration, and other characteristics as described elsewhere herein. For instance, the III-nitride alloy layer 506 may be composed of, or otherwise include, ScAlN, and/or be ferroelectric, while the substrate 508 may be composed of, or otherwise include silicon. Alternatively or additionally, the III-nitride alloy layer 506 may have a surface roughness as described herein.

In the example of FIG. 5, the III-nitride alloy layer 506 is not in contact with the substrate 508. Instead, the buffer layer 504 may be in contact with the substrate 508. The buffer layer 504 may be composed of, or otherwise include, a III-nitride or other semiconductor material, such as GaN. Still other materials may be used as, or otherwise in connection with, a buffer layer, including, for instance, a single-crystal metal layer composed of, e.g., Al, Pt, Mo, and/or another metal.

In some cases, the buffer layer 504 may have the same composition as, or otherwise include the material of, the III-nitride alloy layer 506. For example, both the III-nitride alloy layer and the buffer layer may be composed of, or otherwise include, ScAlN. One or more characteristics of the III-nitride alloy layer and the buffer layer may nonetheless be different. For example, the buffer layer may not be ferroelectric.

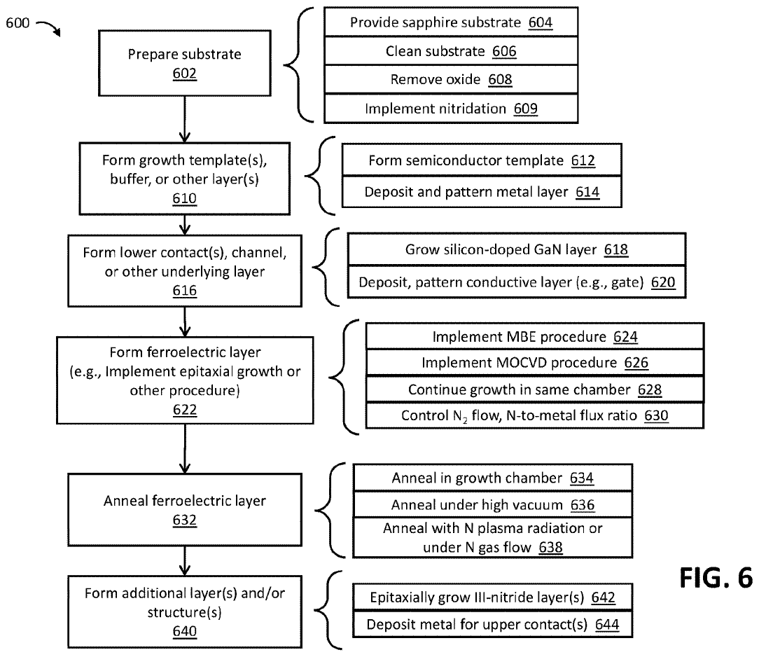

FIG. 6 depicts a method 600 of fabricating a heterostructure having a layer (or wurtzite structure) of an alloy of a III-nitride material with scandium and/or another IIIB element incorporated therein in accordance with one example. As described herein, the method 600 is configured such that the III-nitride alloy layer may be grown on a silicon substrate. The method 600 may be configured such that the wurtzite structure exhibits ferroelectric behavior. The heterostructure may form a device, or a part of a device, in which one or more layers or regions of the device exhibit the ferroelectric behavior. The method 600 may be used to fabricate the examples of ScₓAl₁₋ₓN films and layers described herein.

The method 600 may begin with an act 602 in which a substrate is prepared and/or otherwise provided. In some cases, the act 602 includes providing a silicon substrate in an act 604. The silicon substrate may have a (111) orientation. The substrate may be patterned or otherwise processed to configure the substrate to reduce defect formation in subsequently grown layers of the heterostructure and/or otherwise improve material quality therein. Such processing may also facilitate the formation of a different regions of the heterostructure.

Alternative or additional substrate materials may be used, including, for instance, sapphire, bulk GaN, bulk AlN, or other semiconductor material. Still other materials may be used, including, for instance, silicon carbide. In still other cases, a metal substrate may be used. For instance, the metal substrate may be composed of, or otherwise include, Al, Pt, and/or Mo.

The substrate may be cleaned in an act 606. In some cases, a native or other oxide layer may be removed from a substrate surface in an act 608. The oxide removal may include multiple steps, including, for instance, an etch step and a baking step.

In some cases, the act 602 includes implementing a nitridation procedure in an act 609. Nitriding the surface may help avoid the formation of a eutectic layer upon or during growth of the heterostructure. As described above, the nitridation procedure may be alternatively or additionally performed after the growth of a semiconductor template or other layer (e.g., a GaN layer) in connection with (or as part of), for instance, an act 610 addressed below.

Additional or alternative processing may be implemented in other cases, including, for instance, doping or deposition procedures. The substrate thus may or may not have a uniform composition. The substrate may be a uniform or composite structure.

The method 600 may include an act 610, in which one or more growth templates, buffer, or other layers are formed. The layer(s) are thus formed on, or otherwise supported by, the substrate. The layer(s) may or may not be in contact with the substrate. In some cases, the layer(s) are composed of, or otherwise include, a semiconductor material. For instance, the act 610 may include an act 612 in which a semiconductor layer is formed. For example, a III-nitride layer, such as a GaN layer, may be grown or otherwise formed on the substrate. Other compound or other semiconductor materials may be used, including, for instance, AlGaN. The semiconductor layer(s) may be N-polar, metal-polar, or alternating or otherwise mixed polarity (e.g., periodically poled structures). The semiconductor layer(s) may form a part of the heterostructure underlying the ferroelectric or III-nitride alloy layer to be grown. The semiconductor layer be undoped or doped (e.g., Si-doped). The act 612 may thus be implemented before (e.g., in preparation for) implementing an epitaxial growth procedure in which a wurtzite structure is formed. The wurtzite structure may thus be formed on the semiconductor layer. The semiconductor layer may be configured or used as a growth template for the wurtzite structure and/or other elements of the heterostructure. In some cases, the act 612 may include growing the semiconductor layer in an epitaxial growth chamber in which the epitaxial growth procedure for the wurtzite structure is implemented. As a result, the substrate may remain within, e.g., is not removed from, the epitaxial growth chamber between forming the semiconductor layer and implementing the epitaxial growth procedure for growing the wurtzite structure.

Alternatively or additionally, the act 610 includes an act 614 in which one or more metal or other conductive layers are deposited and patterned. For example, an aluminum layer may be deposited on a silicon substrate in preparation for the epitaxial growth of the wurtzite structure.

In some cases, no growth template, buffer layer, or other layer is grown or formed, as described herein.

The method 600 may include an act 616 in which one or more contacts or other layers are formed. The layer(s) may form a part of the heterostructure underlying the ferroelectric layer to be grown. Examples of the underlying layer(s) include a lower or bottom contact of the heterostructure or a channel layer of the heterostructure. The nature of the underlying layer(s) may vary with the device being fabricated. In some cases, the act 616 includes growing a silicon-doped GaN layer in an act 618. The Si-doped GaN layer may be N-polar or metal-polar. Other materials may be used. For instance, the underlying layer(s) may be composed of, or otherwise include, AlGaN, InAlN, InGaN, or InAlGaN. Still other materials may be used. For instance, a channel layer may be composed of, or otherwise include, other types of semiconductors, e.g., Ga₂O₃, diamond, Si, SiGe, GaAs, InGaAs, or InP, in addition to one or more of the above-referenced III-nitride alloys. Additional or alternative conductive structures, such as a gate structure, may be deposited and/or patterned in an act 620.

In an act 622, a non-sputtered epitaxial growth procedure is implemented to form a layer of an alloy of a III-nitride material. The layer is in contact with or otherwise supported by the substrate, as described herein. The III-nitride alloy layer may or may not be ferroelectric. As described herein, the III-nitride alloy layer has a wurtzite structure. For instance, the III-nitride material may be AlN. Additional or alternative III-nitride materials may be used, including, for instance, gallium nitride (GaN), indium nitride (InN), and their alloys. As also described herein, the epitaxial growth procedure is configured to incorporate scandium and/or another group IIIB element into the alloy of the III-nitride material. The alloy may thus be ScₓAl₁₋ₓN, for example. In some cases, the act 622 includes an act 624 in which an MBE procedure is implemented. In other cases, an MOCVD or other non-sputtered epitaxial growth procedure is implemented in an act 626.

The act 622 may constitute a continuation, or part of a sequence, of growth procedures. The growth procedures may be implemented in a common, or same, growth chamber. The act 622 may thus include an act 628 in which epitaxial growth is continued in the same chamber in which one or more other layers of the heterostructure were grown. For instance, one or more of the growth template and the underlying semiconductor layer(s) formed in the acts 610 and 616 may be formed in the same chamber as the ferroelectric layer. Sequential layers of the heterostructure may thus be grown without exposure to the ambient. The quality of the interface between the layers may accordingly be improved.

The growth temperature may be at a level such that the wurtzite structure exhibits a breakdown field strength greater than a ferroelectric coercive field strength of the wurtzite structure. Ferroelectric switching and other behavior may thus be achieved.

The growth temperature may be at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single crystal of the scandium-including alloy (e.g., a monocrystalline layer of the alloy) at the growth temperature level may nonetheless be achieved. For example, in some cases, a ScₓAl₁₋ₓN alloy may be epitaxially grown at a growth temperature of about 650 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius or lower would result in structures of such poor quality so as to be useless. In contrast, the epitaxially grown ScₓAl₁₋ₓN layer grown at that low temperature is unexpectedly monocrystalline and of high quality.

Growth of the ScₓAl₁₋ₓN layer at the conventional AlN growth temperature (and other temperatures above the upper bound) unexpectedly results in the formation of dislocations and/or other leakage paths in the ScₓAl₁₋ₓN layer. With the leakage paths, the ScₓAl₁₋ₓN layer has a breakdown field strength level too low (e.g., below the ferroelectric coercive field strength level). The layer accordingly does not exhibit ferroelectric behavior.

In some cases, the growth temperature may be about 650 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 680 degrees Celsius, or about 690 degrees Celsius. In still other cases, the upper bound may be lower, including, for instance, about 600 degrees Celsius or about 620 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming ScₓAl₁₋ₓN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

The above-noted differences in crystal quality evidenced via x-ray diffraction rocking curve line widths may also be used to distinguish between monocrystalline and polycrystalline structures. As used herein, the term “polycrystalline” refers to structures having x-ray diffraction rocking curve line widths on the order of a few degrees or higher, and/or in-plane rotation. As used herein, the term “monocrystalline” refers to structures having x-ray diffraction rocking curve line widths at least one order of magnitude lower than the order of a few degrees without in-plane rotation, e.g., as indicated by x-ray φ scans.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

The wurtzite structure of the ferroelectric layer may be nitrogen-polar (N-polar) or metal-polar. The polarity of an underlying layer formed in the act 610 and/or the act 616 may be used to establish the polarity of the ferroelectric layer formed in the act 622. As described herein, the polarity of the underlying layer may, in turn, be established by a characteristic of the substrate. The polarity may continue across the interface between the underlying layer and the ferroelectric layer. Either N- or metal-polarity may thus persist as the composition changes from the underlying layer to the ferroelectric layer.

In some cases, the epitaxial growth procedure is implemented under a nitrogen-rich condition. For example, the nitrogen-to-metal flux ratio may be set in an act 630 in which the nitrogen flow is controlled. In some cases, the unbalanced flux ratio may be set to a highly or extremely nitrogen (N)-rich condition, such as a N-to-metal flux ratio of 2-to-1 or higher.

Control of the flux ratio between metal and nitrogen sources may be useful for improving the material quality of the ScₓAl₁₋ₓN or other III-nitride alloy layer. As described herein, the N-rich growth conditions may be useful in connection with the growth of ScₓAl₁₋ₓN to avoid Sc—Al intermetallic, Sc₃AlN perovskite phase formation, and/or other defects.

In some cases, the wurtzite structure may then be annealed in an act 632. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScₓAl₁₋ₓN may be performed in-situ in the same growth chamber (e.g., the same MBE chamber) in an act 634. In other cases, the annealing is performed ex-situ in a chamber directed to annealing procedures.

The annealing process may be implemented under high vacuum in an act 636 (e.g., in-situ in the growth chamber). In other cases, the annealing may be implemented either with nitrogen plasma radiation or under nitrogen gas flow in an act 638.

The above-described annealing procedure may be implemented in connection with films grown under any of the above-described growth conditions. For instance, the annealing procedure may be implemented after growth under slightly to moderately N-rich conditions at a growth temperature below about 650 degrees Celsius. The annealing procedure may also be implemented after growth under unbalanced flux ratios (e.g., N-rich or extreme N-rich conditions) at growth temperatures above about 650 degrees Celsius.

The method 600 may include an act 640 in which one or more layers (e.g., semiconductor layers) are formed after growth of the wurtzite structure. As a result, the layer(s) may be in contact with the wurtzite structure. For instance, one or more III-nitride (e.g., GaN or AlGaN) or other semiconductor layers may be epitaxially grown in an act 642. The act 642 may be implemented in the same epitaxial growth chamber used to grow the wurtzite structure. As a result, the substrate (and heterostructure) is not removed from the epitaxial growth chamber between implementing the acts 622 and 640.

Alternatively or additionally, the act 640 includes an act 644 in which one or more metal or other conductive layers or structures are formed. The layers or structures may be deposited or otherwise formed. In some cases, the conductive structure is configured as an upper or top contact. For instance, the conductive structure may be a gate.

The method 600 may include fewer, additional, or alternative acts. For example, one or more acts may be directed to forming other structures or regions of the device that includes the heterostructure. In a transistor device example, the regions may correspond with source and drain regions. The nature of the regions or structures may vary in accordance with the nature of the device. In another example, the method 600 does not include an act 610 in which a buffer layer is grown or otherwise formed.

The order of the acts of the method 600 may differ from the example shown in FIG. 6. For example, the acts 616, 618, and 620 in which contacts and/or other conductive structures formed may be implemented after the growth of the ferroelectric layer.

A number of different types of devices may be fabricated by the method 600 of FIG. 6, and/or another method of fabricating a heterostructure having a wurtzite structure of an alloy of a III-nitride material with scandium incorporated therein. For example, the ferroelectric ScₓAl₁₋ₓN or other alloy of a III-nitride material may be useful in various types of nonvolatile memory devices (e.g., FeRAM, FeFET, FTJ, and FeSFET devices), various types of reconfigurable electronic and other devices (e.g., Fe-HEMT, Fe-capacitor, and SAW devices), various types of photodetection, photovoltaic and optoelectronic devices (e.g., self-driven photodetector and solar cell devices), and various homojunction devices (e.g., devices that use a laterally distributed charge plate to tune the Fermi level in adjacent layers). Still other types of devices may be fabricated, including, for instance, FE-based thin-film bulk acoustic wave resonators (FBAR) devices.

The disclosed heterostructures may be incorporated into a wide variety of devices.

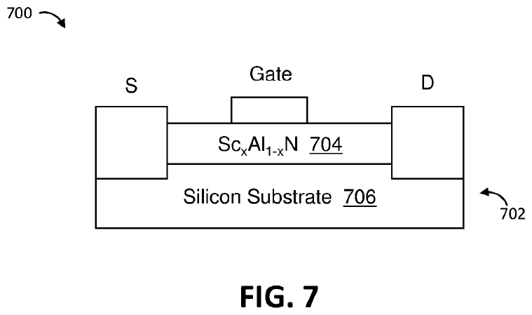

FIG. 7 depicts a device 700 having a heterostructure 702 with a buffer-free ferroelectric layer 704 in accordance with one example. In this case, the device 700 is configured as a ferroelectric transistor device. The transistor device 700 has a ferroelectric layer adjacent a channel layer or region. In the example shown, the ferroelectric layer is the buffer-free ScAlN layer 704. The ferroelectric layer 704 is thus in contact with a substrate 706, such as a silicon substrate, as in this example. The ferroelectric layer 704 may include any one or more features or otherwise be configured (e.g., with an atomically smooth surface) as described elsewhere herein. In other cases, the buffer-free ScAlN layer 704 is not ferroelectric.

In operation, the modulated polarization in the ferroelectric layer 704 attracts electrons and holes in opposite directions, thereby tuning the carrier density inside the channel region or material, forming, e.g., a nonvolatile memory or a steep-slope transistor device. The transistor and its channel may be formed in semiconductors such as GaN, Si, etc.

Described above are heterostructures that illustrate, and make use of, the effect of dislocation density on the ferroelectric properties of single crystalline ScAlN thin films grown by molecular beam epitaxy (MBE). Wurtzite phase and atomically smooth ScAlN films have been grown on bulk GaN, GaN on sapphire, and GaN on Si substrates with dislocation densities ranging from ~10⁷ to 10¹⁰ cm⁻². Despite the significant difference in dislocation density, ferroelectricity was observed. The presence of high densities of dislocations, however, results in enhanced asymmetric P-E loops and overestimated remnant polarization values. Further measurements show that the leakage current and breakdown strength can be improved with decreasing dislocation density. As described above, trapping/detrapping assisted transport is the main leakage mechanism in epitaxial ferroelectric ScAlN films. The samples described above establish the material quality considerations for achieving the ferroelectric property of ScAlN in connection with integration with mainstream semiconductor platforms, e.g., Si, thereby paving the way for a wide variety of novel electronic, optoelectronic and piezoelectronic device configurations.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. A device comprising:
a substrate; and
a ferroelectric layer supported by the substrate;
wherein:
the ferroelectric layer comprises an alloy of a III-nitride material,
the alloy comprises a Group IIIB element, and
the substrate comprises silicon.

2. The device of claim 1, further comprising a buffer layer disposed between the substrate and the ferroelectric layer.

3. The device of claim 2, wherein the buffer layer comprises a III-nitride semiconductor layer.

4. The device of claim 2, wherein the buffer layer comprises the alloy of the III-nitride layer.

5. The device of claim 4, wherein the buffer layer is ferroelectric.

6. The device of claim 1, wherein:
the substrate and the ferroelectric layer are arranged as a heterostructure; and
the heterostructure lacks a buffer layer between the substrate and the ferroelectric layer.

7. The device of claim 6, wherein the ferroelectric layer is in contact with the substrate.

8. The device of claim 1, wherein the ferroelectric layer has a surface roughness less than 1 nm or less than 1% of a thickness of the ferroelectric layer.

9. The device of claim 1, wherein the ferroelectric layer has a dislocation density greater than 1×10¹⁰ cm⁻².

10. A device comprising:
a substrate; and
a ferroelectric layer supported by the substrate;
wherein:
the ferroelectric layer comprises an alloy of a III-nitride material,
the alloy comprises a Group IIIB element, and
the ferroelectric layer has a surface roughness less than 1 nm or less than 1% of a thickness of the ferroelectric layer.

11. The device of claim 10, further comprising a buffer layer disposed between the substrate and the ferroelectric layer.

12. The device of claim 11, wherein the buffer layer comprises a III-nitride semiconductor layer.

13. The device of claim 11, wherein the buffer layer comprises the alloy of the III-nitride layer.

14. The device of claim 11, wherein the buffer layer comprises Al, Pt, Mo and/or another metal.

15. The device of claim 10, wherein:
the substrate and the ferroelectric layer are arranged as a heterostructure; and
the heterostructure lacks a buffer layer between the substrate and the ferroelectric layer.

16. The device of claim 10, wherein the ferroelectric layer is in contact with the substrate.

17. The device of claim 10, wherein the substrate comprises a silicon substrate with a (111) orientation.

18. The device of claim 10, wherein the substrate comprises a metal substrate.

19. The device of claim 18, wherein the metal substrate comprises Al, Pt and/or Mo.

20. A device comprising:
a substrate; and
a layer supported by the substrate in a buffer-free configuration, the layer comprising an alloy of a III-nitride material;
wherein:
the alloy comprises a Group IIIB element,
the substrate comprises silicon, and
the layer has a surface roughness less than 1 nm or less than 1% of a thickness of the ferroelectric layer.

21. The device of claim 20, further comprising a buffer layer disposed between the substrate and the layer.

22. The device of claim 21, wherein the buffer layer comprises a III-nitride semiconductor layer.

23. The device of claim 21, wherein the buffer layer comprises the alloy of the III-nitride layer.

24. The device of claim 21, wherein the buffer layer comprises Al, Pt, Mo and/or another metal.

25. The device of claim 20, wherein:
the substrate and the layer are arranged as a heterostructure; and
the heterostructure lacks a buffer layer between the substrate and the layer.

26. The device of claim 20, wherein the layer is in contact with the substrate.

27. A method of forming a heterostructure, the method comprising:
providing a substrate; and
implementing a non-sputtered, epitaxial growth procedure to form a ferroelectric layer supported by the substrate, the ferroelectric layer comprising an alloy of a III-nitride material, the non-sputtered, epitaxial growth procedure being configured to incorporate a group IIIB element into the alloy of the III-nitride material;
wherein:
the substrate comprises silicon; and
the epitaxial growth procedure is implemented under a nitrogen-rich condition.

28. The method of claim 27, wherein providing the substrate comprises nitriding a surface of the substrate.

29. A method of forming a heterostructure, the method comprising:
providing a substrate; and
implementing a non-sputtered, epitaxial growth procedure to form a ferroelectric layer supported by the substrate, the ferroelectric layer comprising an alloy of a III-nitride material, the non-sputtered, epitaxial growth procedure being configured to incorporate a group IIIB element into the alloy of the III-nitride material;
wherein:
the substrate comprises silicon; and
providing the substrate comprises nitriding a surface of the substrate.

30. The method of claim 29, wherein providing the substrate further comprises decomposing a native oxide on a surface of the substrate.
